(19) United States
(12) Patent Application Publication
(10) Pub. No.: US 2008/0135405 A1
(43) Pub. Date: Jun. 12, 2008

(54) Metal Double-Layer Structure and Method For Manufacturing the Same and Regeneration Method of Sputtering Target Employing That Method

(75) Inventors: Hisashi Hori, Shizuoka (JP); Nobushiro Seo, Shizuoka (JP); Tomohiro Komoto, Tokyo (JP); Kazuo Tsuchiya, Tokyo (JP)

Correspondence Address: BIRCH STEWART KOLASCH & BIRCH, PO BOX 747, FALLS CHURCH, VA, 22040-0747, US

(73) Assignee: NIPPON LIGHT METAL COMPAYN, LTD., Tokyo (JP)

(21) Appl. No.: 11/884,878

(22) PCT Filed: Feb. 28, 2006
(86) PCT No.: PCT/JP2006/003704

§ 371 Date: Sep. 26, 2007

(30) Foreign Application Priority Data
Mar. 4, 2005 (JP) 2005-061621

(51) Int. Cl. C23C 14/34; B23K 20/12; B32B 15/01

(52) U.S. Cl. 204/298.12; 228/112.1; 428/650; 428/654; 228/114

(57) ABSTRACT

Provided is a metal double-layer structure in which a modified metallic member modified from a flat plate metallic member is bonded to be stuck to a plate material, manufacturing method thereof, and a method of regenerating a sputtering target using the method. The method includes the steps of: overlapping the plate material with the metallic member; inserting a rotary tool having a rotor and a probe projecting from a bottom surface of the rotor into a surface of the metallic member while rotated; bringing a distal end of the probe to a position close to a mating plane between the metallic member and the plate material to generate friction heat and stir the distal end, and moving the rotary tool to form adjacent motion tracks on the surface of the metallic member; and forming stirred areas along the mating plane to bond the metallic member and the plate material together, and modifying the metallic member into a modified metallic member.

### TECHNICAL FIELD

The present invention relates to a method of manufacturing a metal double-layer structure including a modified metallic member and a plate material, the method including the steps of inserting a rotary tool into the surface of a flat plate metallic member overlapped with the plate materia and carrying out friction stirring for bonding the metallic member to the plate material, to thereby modify the metallic member so as to obtain the modified metallic member. The present invention also relates to a metal double-layer structure manufactured by using the method, and to a method of regenerating a sputtering target to obtain a new sputtering target by recycling a used sputtering target by the method.

### BACKGROUND ART

Film formation performed by sputtering is widely used in the manufacture of various products such as semiconductor devices, magnetic disks, optical disks, liquid crystals, and flat panel displays typified by plasma displays. For performing film formation by sputtering, there is used a sputtering target including a backing plate serving as a support having cooling means bonded to a target material to the rear side thereof, which is a raw material of a thin film.

It is desired that the target material should be uniform in composition and metal structure so that a high-quality film having uniform thickness and composition can be formed by sputtering. For example, there is reported a target material containing crystal grains having an average particle size of 20 μm or less in the crystal structure, paying attention to a phenomenon that generation of particles and a splash occur frequently in a target material which contains large crystal grains in the inside structure during sputtering (refer to Patent Document 1). When such a target material is used, generation of particles or the like is minimized and a high-quality film can be formed by preventing a short-circuit, in a thin film circuit, which is caused by formation of a projection in a thin film due to scattering of giant particles, and abnormal discharge. In order to prevent generation of particles and a splash, there is also reported a target material which is obtained by being mixed with an alloy element in order to reduce the grain size of crystals forming the target material and reduce the electric resistance of a thin film (refer to Patent Document 2).

However, in order to obtain the target material of the afore-mentioned Patent Document 1, a cast material such as a slab or billet needs to be subjected to heat treatment such as homogenization and to high plastic forming through hot rolling at a suitable temperature for forming fine re-crystals. The method is complicated and involves high costs, and it is difficult to completely eliminate the component segregation of the metal solid structure of the cast material itself. In order to obtain the target material of the Patent Document 2, a spray forming, powdering method, or the like need to be used to manufacture the target material for making composition including an alloy element uniform. Because HIP or extrusion must be performed to make the target material dense in those methods, the size of the target material to be molded is limited and the cost rises in the current situation where the sputtering target is becoming larger in size as will be described below.

A target material and a backing plate are bonded together by soldering and the like. As a sputtering facility is getting larger in size, the temperature to be applied to the sputtering target itself is becoming higher. When the temperature to be applied to the sputtering target rises as described above, there is a possibility that portions to be bonded together by soldering may melt and the target material may come off from the backing plate. Then, there are reported a technology for bonding the target material and the backing plate together by inserting an insert material made of indium between the target material and the backing plate (refer to Patent Document 3) and a technology for bonding the backing plate and the target material together by hot isostatic press by forming a titanium layer and an aluminum-magnesium alloy interstitial layer on the bonding surface of the backing plate (refer to Patent Document 4).

However, the bonding technology in which expensive indium is used in the insertion material has a problem of cost, which becomes obvious particularly when a large-sized sputtering target is manufactured. Meanwhile, the technology of the Patent Document 4 has a problem of cost because the step of forming a titanium layer and an interstitial layer is added, the apparatus for allowing high-pressure HIP is expensive and the bonding area cannot be made large. Therefore, a large-sized target material cannot be manufactured.

As described above, as a flat panel display such as a liquid crystal display is becoming larger in size and more inexpensive, a glass substrate having an area of more than 1 m² must be handled. Therefore, the development of a large-sized sputtering target is hoped for. However, it is technically difficult to obtain a large-sized single target material which makes it possible to form a film having a uniform thickness and composition on a glass substrate having an area of more than 1 m². For example, in the technologies of the Patent Documents 1 and 2, the manufacture of the target material is limited by the apparatus and the obtained target material does not become fine and uniform in structure when a large-sized apparatus is used. Then, there is proposed a technology for obtaining a target material having a surface area of more than 1 m² by preparing a plurality of target materials and bonding the end surfaces thereof together by solid-phase diffusion (refer to Patent Document 5), a multi-division sputtering target in which a plurality of target materials are bonded to a backing plate (refer to Patent Documents 6 and 7) or the like. That is, increasing in size of the sputtering target is one of the important themes nowadays.

When a sputtering target is used in a sputtering apparatus, the surface of a target material is worn away and gradually becomes uneven. Such an unevenness may cause abnormal discharge or make the obtained film nonuniform in thickness. When the sputtering target is continuously used in this state, the bonding plane between the target material and the backing plate is exposed and impurities may be contained in the obtained film. Then, the sputtering target is exchanged for a new one at a predetermined cumulative time with a certain margin before those problems emerge. In this case, the used sputtering target can be recycled by bonding a new target material by soldering after the worn-away target material is removed from the backing plate by chemical or mechanical means and cleaned or polished. However, because it takes time, effort, and cost to recycle the used sputtering target, there arises a problem in that the used sputtering target is often scrapped and all the remaining target material and the backing plate in a still good state are thrown away.

The inventors of the present invention proposed in the previous application a method of agitating the surface of a cast with a rotary tool used for friction-stir welding as a method of removing minute voids present near the surface layer of the cast and fine unevenness on the cast skin of the surface of the cast (refer to Patent Document 8). The method is to remove minute voids on the surface of the cast. The inventors of the present invention also proposed in the previous application a method of applying the friction stir welding to metallic members by overlapping the metallic members having different melting points with each other and inserting a rotary tool into the surface of a metallic member having a lower melting point (refer to Patent Document 9). The method aims to simply bond the metallic members together.

Patent Document 1: JP 10-330927 A

Patent Document 2: JP 2000-199054 A

Patent Document 3: JP 2001-262332 A

Patent Document 4: JP 2002-294440 A

Patent Document 5: JP 2004-204253 A

Patent Document 6: JP 2000-204468 A

Patent Document 7: JP 2000-328241 A

Patent Document 8: JP 3346380 A

Patent Document 9: JP 2002-79383 A

### DISCLOSURE OF THE INVENTION

### Problems to be Solved by the Invention

The inventors of the present invention have conducted intensive studies on a sputtering target manufacturing method which can provide a target material capable of forming a high-quality film by sputtering, has high reliability for bonding between the target material and a backing plate, and can meet the requirement for a large-sized sputtering target. As a result, they have found that when a rotary tool is inserted into the surface of a metallic member overlapped with a backing plate to generate friction heat and stir it, the metallic member and the backing plate can be bonded together without fail and a target material having a fine crystal grain size can be obtained through modification of the metallic member. The present invention has been accomplished based on those findings.

By using the method described above, a metal double-layer structure in which a modified metallic member having a crystal structure with a fine crystal grain size is bonded to a plate material can be obtained and used as a member for semiconductor electronic materials including a sputtering target described above. The metal double-layer structure can be used as a panel for construction materials or an external panel for transport machines in which the modified metallic member is used as a high corrosion resistant member subjected to a surface treatment resulting from a fine crystal grain structure, or as a highly molded plate material in which the modified metallic member is used as a highly rolled member resulting from a fine crystal grain structure.

It is therefore an object of the present invention to provide a method of manufacturing a metal double-layer structure in which a modified metallic member having a fine crystal grain size is reliably bonded to a plate material, in particular, a metal double-layer structure suitable for use as a sputtering target in which a target material suitable for the formation of a high-quality film is reliably bonded to a backing plate.

It is another object of the present invention to provide a metal double-layer structure in which a modified metallic member having a fine crystal grain size is reliably bonded to a plate material, in particular, a metal double-layer structure suitable for use as a sputtering target in which a target material suitable for the formation of a high-quality film is reliably bonded to a backing plate.

Further, it is still another object of the present invention to provide a sputtering target regenerating method which makes effective use of a used sputtering target to regenerate the used sputtering target into a sputtering target having a high-quality target material easily by using the method of manufacturing a metal double-layer structure described above.

### Means for Solving the Problems

The present invention relates to a method of manufacturing a metal double-layer structure formed by bonding a modified metallic member obtained by modifying a flat plate metallic member to a plate material to join them together, including the steps of: overlapping the plate material with the metallic member; inserting a rotary tool having a rotor and a probe projecting from a bottom surface of the rotor into a surface of the metallic member while rotated; bringing a distal end of the probe to a position close to a mating plane between the metallic member and the plate material to generate friction heat and stir the distal end and moving the rotary tool to form adjacent motion tracks on the surface of the metallic member; and forming stirred areas along the mating plane to bond the metallic member and the plate material together, and modifying the metallic member into a modified metallic member.

The present invention also relates to a metal double-layer structure formed by bonding a modified metallic member obtained by modifying a flat plate metallic member to a plate material to join them together, the structure including: the plate material overlapped with the metallic member; a rotary tool, having a rotor and a probe projecting from the bottom surface of the rotor, inserted into the surface of the metallic member while rotated; a distal end of the probe brought to a position close to a mating plane between the metallic member and the plate material to generate friction heat and stir the distal end, the rotary tool which is moved to form adjacent motion tracks on the surface of the metallic member; and stirred areas formed along the mating plane to bond the metallic member and the plate material together, and the metallic member which is modified into a modified metallic member.

Further, the present invention relates to a method of regenerating a sputtering target by bonding a target material which is a modified metallic member obtained by modifying a flat plate metallic member to a used sputtering target to joint them together, including the steps of: grinding or polishing the surface of the used sputtering target to form a regenerated reference plane; overlapping a metallic member with the regenerated reference plane; inserting a rotary tool having a rotor and a probe projecting from a bottom surface of the rotor from a surface of the metallic member while rotated; bringing a distal end of the probe to a position close to the regenerated reference plane to generate friction heat and stir the distal end; and moving the rotary tool to form adjacent motion tracks on the surface of the metallic member to form stirred areas along the regenerated reference plane so as to bond the metallic member to the regenerated reference plane and modifying the metallic member into a modified metallic member.

A case where a sputtering target as a preferred example of the metal double-layer structure of the present invention, that is, a sputtering target in which a target material composed of a modified metallic member is bonded to a backing plate (plate material) will be described below. Because the metal double-layer structure of the present invention can be applied to a purpose other than the sputtering target, the present invention is not limited thereto.

In the present invention, the rotary tool having the rotor and the probe projecting from the bottom surface of the rotor is inserted into the surface of a metallic member while rotated to allow the distal end of the probe to reach a position close to the mating plane between the metallic member and the backing plate, the metallic member is softened by friction heat generated by the movement of the rotary tool, and a stirred area is formed by friction stirring. While rotated, the rotary tool is moved to form adjacent motion tracks in a predetermined planar area on the surface of the metallic member. As a result, stirred areas are formed along the mating plane between the metallic member and the backing plate, the metallic member and the backing plate are joined together by solid-phase bonding by using the stirred areas, and the stirred areas of the metallic member are modified to obtain a modified metallic member. When the rotary tool is moved such that the motion tracks of the rotary tool are adjacent to each other in the predetermined planar area on the surface of the metallic member, the stirred areas formed along the tracks to follow the motion tracks of the rotary tool are obtained in the state where the motion tracks are adjacent to each other. As a result, the metallic member and the backing plate are bonded together without fail, and the modification of the metallic member can be carried out in the predetermined planar area of the metallic member without fail. Since bonding between the metallic member and the backing plate is solid-phase by bonding using the stirred areas formed by the rotary tool, the bonded portions become a method structure, thereby producing no defect specific to melt welding such as a shrinkage hole or a blow hole. The metallic member and the backing plate are directly bonded together, so it is not necessary to form a low-melting point layer on the bonding surface like soldering. Therefore, there is no possibility that the metallic member and the backing plate are separated from each other by a temperature rise and that thermal conductivity between the metallic member and the backing plate is inhibited.

As for the stirred areas formed along the mating plane between the metallic member and the backing plate, they may be formed in both the metallic member and the backing plate with the mating plane therebetween to bond together the metallic member and the backing plate by friction-stir welding. The stirred areas may be formed only in the metallic member to reach the mating plane to bond them together in view of preventing the component of the backing plate from being contained in the modified metallic member.

As for the movement of the rotary tool, the rotary tool may track any movement tracks as long as the rotary tool is moved so that the motion tracks of the rotary tool, which are adjacent to each other, are formed in a predetermined planar area on the surface of the metallic member. For example, linear movement may be repeated several times to form motion tracks. Preferably, the rotary tool is moved continuously, for example, rotated around or rotated at a right angle or an arbitrary angle in the predetermined planar area such that motion tracks become adjacent to each other. According to such a continuous movement, by minimizing the number of times of inserting and removing the rotary tool, the metallic member can be modified more uniformly and the number of draw holes of the rotary tool formed on the surface of the metallic member can be made as small as possible. As for the adjacent motion tracks of the rotary tool, the motion tracks are preferably formed such that they have an overlapped portion and more preferably formed such that the overlapped portion formed at the distal end portion of the probe is 0.5 to 2.0 mm wide in view of more reliable modification of the metallic member.

In the present invention, the stirred areas formed by the rotary tool are formed by plastic flow, and it is probable that dynamic re-crystallization occurs during agitation with the rotary tool and that static re-crystallization occurs by residual heat after the rotary tool is moved away. Therefore, the metallic member in which the stirring areas are formed by the rotary tool is modified into a fine crystal structure having a fine grain size to obtain a modified metallic member. When sputtering is carried out by using the obtained modified metallic member as a target material, the generation of particles and a splash phenomenon can be prevented. When the metallic member is a cast material or rolled material, the segregation of the contained component can be eliminated by the plastic flow, thereby making it possible to obtain a modified metallic member which is uniform in composition and metal structure and to form a homogeneous film by sputtering. Further, the recrystallized grains of the fine crystal structure have a random direction by the plastic flow, so the crystal anisotropy of the metallic member is eliminated, thereby making it possible to form a film uniform in thickness by sputtering. In order to further improve those effects, it is preferred to obtain a modified metallic member composed of a fine crystal structure having a crystal grain size of 20 μm or less. In order to check the grain size of the modified metallic member, for example, a crosscut method which will be described in Examples may be used.

In the present invention, a cast material, rolled material, forged material, extruded metal, and the like may be used as the flat plate metallic member. The materials of those metallic members are aluminum, titanium, silver, alloys thereof, and the like out of which aluminum or aluminum alloy is preferred. Since aluminum or aluminum alloy has high electric conductivity, they are preferred as a material for films which need to have high electric conductivity. Since they have a relatively low melting point, the metallic member and the backing plate can be bonded together at a softening temperature of about 300 to 500° C. and a modified metallic member can be obtained.

A backing plate for forming a sputtering target may be used as the backing plate and may have a channel for flowing a heat medium or a screw hole or flange for being attached to a sputtering apparatus like an ordinary backing plate. The material of the backing plate is preferably copper, aluminum, or aluminum alloy for excellent heat conductivity thereof.

A rotary tool which is generally used for friction-stir welding may be used as the rotary tool used in the present invention. More specifically, a rotary tool having a rotor and a probe projecting from the center of the bottom surface of the rotor is preferred. As for the probe, threads or irregularities may be formed along the outer wall of the probe, irregularities or a lattice may be formed at the distal end of the probe, or the planar shape of the distal end of the probe may be made circular or polygonal such as tetragonal, pentagonal, or hexagonal. The shape of the rotor may be cylindrical or conical, or a projecting spiral may be formed from the periphery of the bottom surface toward the proximal end of the probe.

In order to insert the rotary tool into the surface of the metallic member, it is preferred that the bottom surface of the rotor should be held into contact with the surface of the metallic member, that is, the bottom surface of the rotor should come in contact with the metallic member. It is more preferred that the bottom surface of the rotor should be buried into the surface of the metallic member by about 0.5 to 1 mm. By rotating the rotary tool so that the bottom surface of the rotor comes into contact with the surface of the metallic member, the stirred areas can be formed on the surface of the metallic member without fail. As for the distal end of the probe which is brought to a position close to the mating plane between the metallic member and the backing plate, it is preferably brought to a position ±1.0 mm from the mating plane. In view of preventing impurities from being contained in the target material when the component of the backing plate is mixed into the modified metallic member at the time of forming the stirred areas, the rotary tool is inserted preferably such that there should be a predetermined interval between the mating plane and the distal end of the probe, more preferably such that the interval between the distal end of the probe and the mating plane, which differs according to the materials of the metallic member and the backing plate, should be about 0.1 to 0.5 mm.

As for the relationship between the length of the probe and the thickness of the metallic member, which differs according to the material of the metallic member, in general, the length of the probe is preferably about 0.5 to 1 mm smaller than the thickness of the metallic member. Since the rotary tool is buried into the surface of the metallic member by about 0.5 mm, when the difference between the length of the probe and the thickness of the metallic member is smaller than 0.5 mm, the distal end of the probe reaches the backing plate. As a result, there may be a difference in the function of agitation with the rotary tool, and the component of the backing plate may be contained in the modified metallic member.

As for the rotation speed and the traverse speed of the rotary tool, which differ according to the material of the metallic member, when the metallic member is made of aluminum or aluminum alloy, the ratio (B/A) of the peripheral speed B of the bottom surface of the rotor with respect to the traverse speed A of the rotary tool is preferably in the range of 70 to 370. The ratio (C/A) of the peripheral speed C of the probe to the traverse speed A of the rotary tool is preferably in the range of 30 to 90. When the B/A is lower than 70 and the C/A is lower than 30, the traverse speed of the rotary tool becomes much higher than the rotation speed of the rotary tool, whereby the softening of a portion around the rotary tool is delayed, and a load is applied to the rotary tool due to increased torque. As a result, a tunnel defect may be produced in the stirred areas due to processing variations, or the rotary tool may stop according to the circumstances. Meanwhile, when the B/A is higher than 370 and the C/A is higher than 90, the traverse speed of the rotary tool becomes low, and the temperature of the stirred areas rises too high with the result that burrs may be produced.

As for the sputtering target in which the target material composed of a modified metallic member is bonded to the backing plate, which is obtained by the present invention, annealing is preferably carried out after the modified metallic member is obtained by modifying the metallic member. Residual stress generated by heating or cooling due to friction stirring with the rotary tool may be present in the sputtering target obtained by bonding together the metallic member and the backing plate by the method described above. When such stress remains, it is possible that distortion may occur in the sputtering target by heating for the formation of a film by sputtering. Then, in order to alleviate the residual stress, the obtained sputtering target is preferably annealed. Since crystal orientation is changed by a plastic flow in the stirred areas formed by the rotary tool, an agitation mark is formed along the motion tracks of the rotary tool on the surface of the obtained modified metallic member. Then, re-crystallization is promoted by annealing to partially alleviate crystal orientation, thereby making it possible to erase the agitation mark. As for the annealing conditions, which differ according to the material of the metallic member or the like, when the metallic member is made of aluminum or aluminum alloy, annealing is preferably carried out at 150 to 350° C. for 1 to 4 hours.

A new sputtering target can be obtained from the used sputtering target by using the method of manufacturing a sputtering target. In this case, the used sputtering target refers to a sputtering target which has been used in a sputtering apparatus until the initial use estimated time, reaching a predetermined cumulative time which is the index of its exchange time, a sputtering target which cannot be used as it is because the surface of the target material is damaged during use for some reason, or a sputtering target which is judged as defective because the target material does not have a specified size when the sputtering target is manufactured.

In the regeneration method of the present invention, the surface of the used sputtering target described above is made flat by cutting or polishing with a machine to form a regenerated reference plane and the metallic member described above is placed on the regenerated reference plane. Then, as described above, the rotary tool having a rotor and a probe projecting from the bottom surface of the rotor is inserted into the surface of the metallic member to cause the distal end of the probe to reach a position close to the regenerated reference plane, thereby generating friction heat and stirring it. The rotary tool is moved to form adjacent motion tracks in the predetermined planar area of the metallic member to form stirred areas along the regenerated reference plane. In this way, the metallic member is bonded to the regenerated reference plane and is modified to obtain a modified metallic member. Since the modified metallic member thus obtained can be used as a target material capable of forming a high-quality film like the modified metallic member described above and is bonded to the regenerated reference plane without fail, the used sputtering target can be re-used as a new sputtering target.

When the regenerated reference plane is formed of part of the e used target material of the used sputtering target, that is, when the used target material remains in the used sputtering target to be regenerated with a certain thickness and the original target material (used target material) still remains to form the regenerated reference plane even after surface thereof is cut or polished, the stirred areas are preferably formed in both the metallic member and the used target material with the regenerated reference plane therebetween. When the stirred areas are formed in both of those materials with the regenerated reference plane therebetween, the metallic member is bonded to the regenerated reference plane more reliably, and minute voids and an oxide film which may be present on the regenerated reference plane formed by polishing can be removed by a plastic flow. When the metallic member used herein is made of the same material as the original target material of the used sputtering target, the difference in the quality of the target material between before and after regeneration can be minimized.

Note that, when the rotary tool is inserted, it is preferred that the bottom surface of the rotor should come into contact with the surface of the metallic member and the distal end of the probe should come into direct contact with the used target material.

The metal double-layer structure of the present invention is used as a member for semiconductor electronic materials including the sputtering target described above, a high corrosion resistant member obtained by subjecting the modified metallic member to a surface treatment resulting from a homogeneous fine grain structure, a panel for high corrosion resistance construction materials or external plate for transport machines in which the high corrosion resistant member is bonded to a plate member (high strength material or material having excellent strength), or a highly molded plate material in which the modified metallic member is used as a highly rolled member resulting from a fine grain structure and bonded to a plate material. Among them, in the case of the panel for construction materials and the external plate for transport machines, metallic members made of iron and copper other than those described above for the sputtering target may be used, and metallic members made of aluminum or aluminum alloy are preferred from the viewpoint of surface treating properties. In the case of the panel for construction materials and the external plate for transport machines, iron and titanium plate materials may be used besides those described above. Meanwhile, in the case of the highly molded plate material, various materials may be used for the metallic member and also for the plate material.

### EFFECT OF THE INVENTION

According to the present invention, because the metallic member is bonded to the plate material and modified to obtain a modified metallic member suitable for use as the target material or the like of a sputtering target, the method of manufacturing a sputtering target can be made significantly simple, for example, as compared with the conventional method and a sputtering target can be manufactured at low cost. According to the manufacturing method, in particular, because the metallic member is modified into a modified metallic member while bonded to the plate material by using the rotary tool, the causes of difficulty in increasing the size of the target material, such as restrictions on the apparatus and nonuniformity in metal structure, can be resolved. Thus, the manufacturing method is advantageous for the manufacture of a large-sized sputtering target.

Since the metal double-layer structure obtained by the manufacturing method of the present invention includes a modified metallic member composed of a fine crystal structure having fine grains, even when used as a sputtering target to form a film on a glass substrate, the generation of particles and a splash phenomenon can be prevented, for example. Further, the modified metallic member has a uniform composition and uniform metal structure due to the elimination of the segregation of the component of the metallic member, so the obtained film becomes homogeneous. In addition, the crystal anisotropy of the metallic member is eliminated and the recrystallized grains of the fine crystal structure have a random direction, so a film uniform in thickness can be formed. Since the modified metallic member and the plate material are directly bonded together in the metal double-layer structure, when the metal double-layer structure is used as a sputtering target and heated, the modified metallic member does not come off, for example, due to distortion, and further heat conductivity between the modified metallic member and the plate material can be maintained under a good condition.

Further, the used sputtering target can be regenerated into a new sputtering target easily at low cost by using the manufacturing method described above, and the regenerated sputtering target allows for the formation of a high-quality film by sputtering. Therefore, because effective use can be made of a backing plate which is scrapped in a good state and a target material which is scrapped before it is finished, the manufacturing method is a useful regenerating method from the viewpoint of recycling.

### BRIEF DESCRIPTION OF THE DRAWINGS

FIG. 1 is an explanatory perspective view showing that a rotary tool is inserted into the surface of a metallic member overlapped with a backing plate and is moved in the method of manufacturing a sputtering target of the present invention.

FIG. 2 is an explanatory sectional view (sectional view taken along the line A-A′ of FIG. 1) showing the state of the rotary tool inserted into the metallic member.

FIG. 3(A) is an explanatory side view of the rotary tool, FIG. 3(B) is a bottom view of the rotary tool, and FIG. 3(C) is a sectional view taken along the line B-B′ of FIG. 3(B).

FIG. 4(A) is an explanatory plan view showing the movement of the rotary tool on the surface of the metallic member in the present invention, and FIG. 4(B) is a sectional view taken along the line C-C′ of FIG. 4(A).

FIGS. 5(A) to 5(D) are explanatory plan views showing different movements of the rotary tool on the surface of the metallic member.

FIG. 6 is an explanatory sectional view of a used sputtering target.

FIG. 7 is an explanatory sectional view showing that the rotary tool is inserted into the surface of the metallic member which is overlapped with a regenerated reference plane 12 formed on a used target material.

FIG. 8 are polarization photomicrographs of a stirred area after annealing of the metallic member: FIG. 8(A) shows a stirred area right after friction stirring was carried out at a rotation speed of 1,400 rpm and a traverse speed of 300 mm/min (without annealing); FIG. 8(B) shows a case where the rotation speed was 1,400 rpm, the traverse speed was 100 mm/min, the annealing temperature was 200° C., and the annealing time was 2 hours; FIG. 8(C) shows a case where the rotation speed was 1,400 rpm, the traverse speed was 300 mm/min, the annealing temperature was 200° C., and the annealing time was 2 hours; FIG. 8(D) shows a case where the rotation speed was 1,400 rpm, the traverse speed was 600 mm/min, the annealing temperature was 200° C., and the annealing time was 2 hours; and FIG. 8(E) shows a case where the rotation speed was 1,400 rpm, the traverse speed was 100 mm/min, the annealing temperature was 300° C., and the annealing time was 2 hours.

### DESCRIPTION OF REFERENCE SYMBOLS

1: backing plate, 2: metallic member, 3: rotary tool, 4: rotor, 5: bottom surface of rotor, 5a: projecting spiral, 6: probe, 6a: threads, 7: mating plane, 8: stirred area, 8a: form overlapped portion of stirred area, 9: modified metallic member, 10: used sputtering target, 11: used target material, 11a: surface unevenness, 12: regenerated reference plane

### BEST MODE FOR CARRYING OUT THE INVENTION

Preferred embodiments of the present invention will be described hereinbelow with reference to the accompanying drawings. A sputtering target will be described as a preferred application of the metal double-layer structure, however, the present invention is not limited to this.

[Manufacture of Sputtering Target]

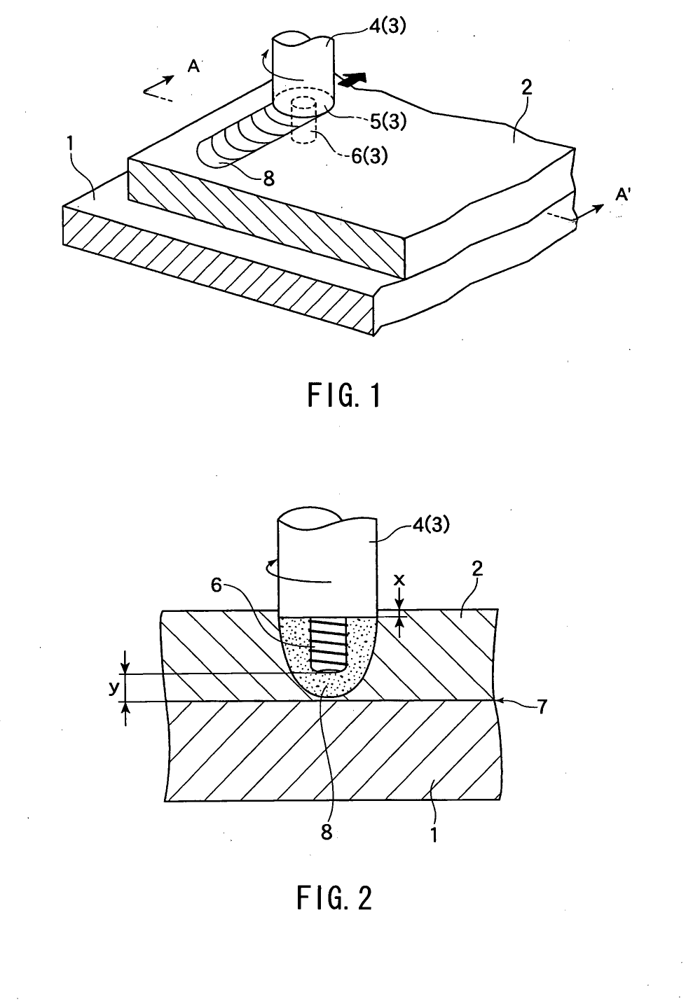

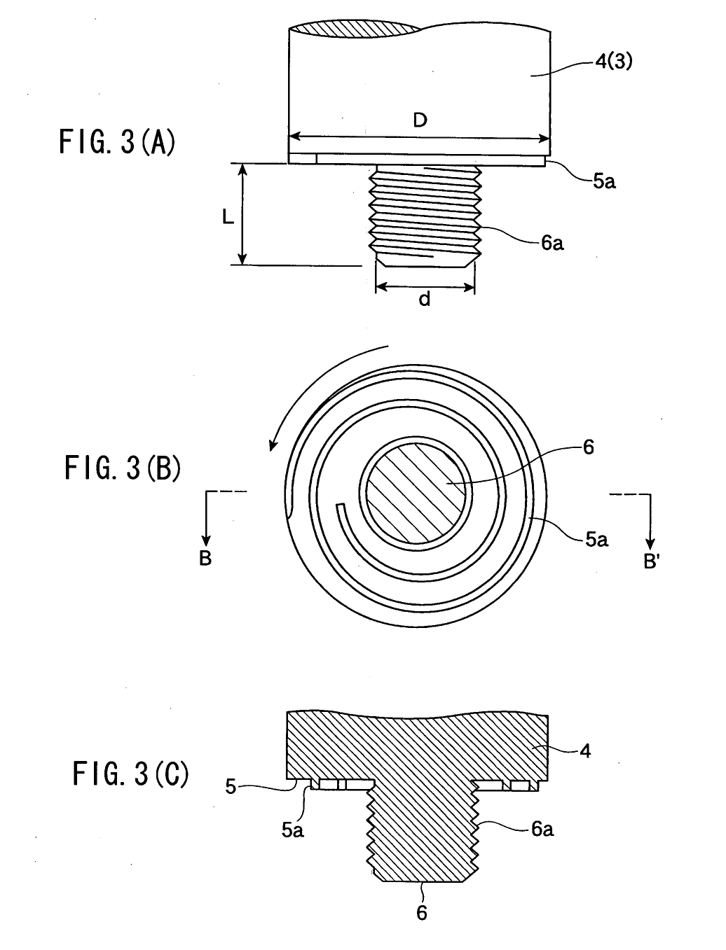

FIG. 1 is an explanatory perspective view showing that a rotary tool 3 is inserted into the surface of a metallic member 2 overlapped with a backing plate (plating material) 1 and is moved in the method of manufacturing the metal double-layer structure of the present invention, and FIG. 2 is a sectional view showing the state of the rotary tool 3 inserted into the metallic member 2 (sectional view taken along the line A-A′ of FIG. 1). As shown in FIG. 1, the flat plate metallic member 2 is first overlapped at a predetermined position of the backing plate 1. The sizes of the backing plate 1 and the metallic member 2 can be suitably designed according to the size and shape of a substrate and the like on which a film is to be formed. In this embodiment, the backing plate land the metallic member 2 having a square plane are used, however, they may have a rectangular, polygonal, or circular plane.

Next, the rotary tool 3 having a cylindrical rotor 4 and a probe 6 projecting coaxially from the center of a bottom surface 5 of the rotor 4 is rotated at a rotation speed of 300 to 1,500 rpm, and 1.5 to 15 kN press force is applied to the surface of the metallic member 2 along the axis of the rotary tool 3 to insert the rotary tool 3 into the surface of the metallic member 2 overlapped with the backing plate 1 so that the bottom surface 5 of the rotor 4 is buried into the surface of the metallic member 2 by x=0.5 to 1.0 mm. In this case, there should be an interval of y=0.1 to 0.5 mm between a distal end of a probe 6 and a mating plane 7 between the metallic member 2 and the backing plate 1. The rotary tool 3 is connected to a rotation drive unit (not shown) so that the rotor 4 and the probe 6 can rotate together and also connected to an X-Y operation shaft (not shown) so that rotary tool 3 can move freely in the planar area of the metallic member 2. As shown in FIGS. 3(A) to 3(C), threads 6a are formed on the outer wall of the probe 6 and a projecting spiral 5a is formed from the periphery of the bottom surface 5 of the rotor 4 toward a proximal end of the probe 6.

A portion around the rotary tool 3 of the metallic member 2 into which the rotary tool 3 is inserted is softened by friction heat and is stirred in a solid-phase state to form an stirred area 8 formed of a plastic flow area. A diameter D of the rotor 4 and a diameter d and a length L of the probe 6 are suitably designed in consideration of the materials and the thicknesses of the metallic member 2 and the backing plate 1, and the rotation speed and the traverse speed of the rotary tool 3 are suitably set so that the stirred area 8 is formed in contact with the mating plane 7 or is formed right before the stirred area 8 comes into contact with the mating plane 7.

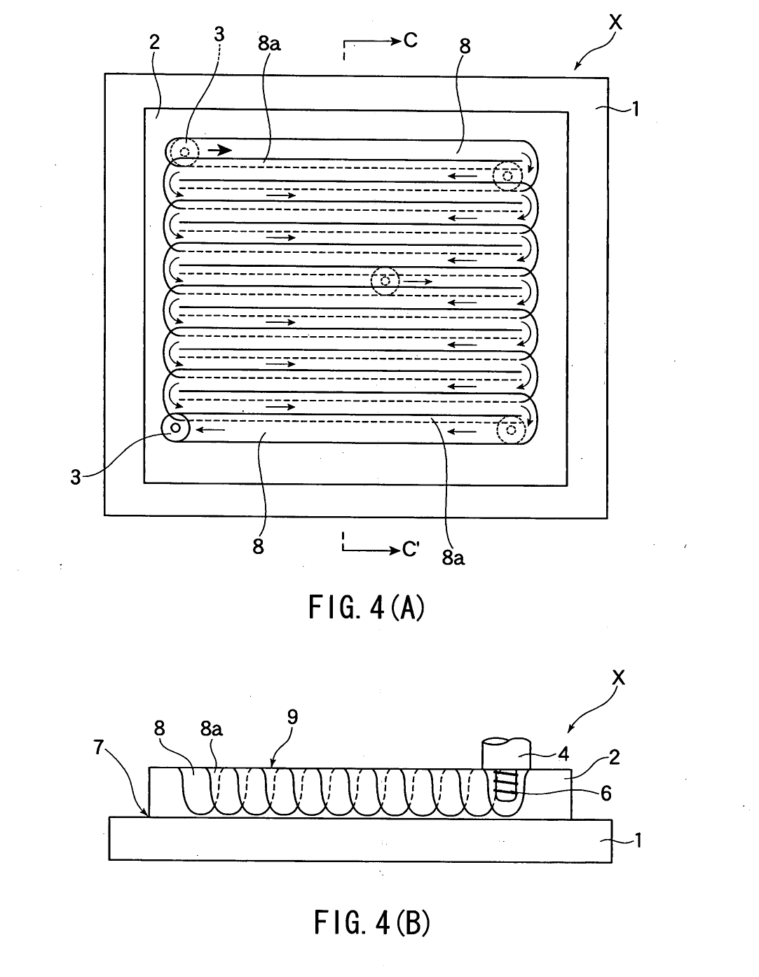

Then, the rotary tool 3 is moved at a speed of 200 to 1,000 mm/min to form adjacent motion tracks in a predetermined planar area of the metallic member 2 while the state described above is maintained. FIG. 4(A) is a plan view showing the movement of the rotary tool 3. As shown in FIG. 4(A), the rotating rotary tool 3 is placed at a position close to a corner (upper left corner in the figure) of the square plane of the metallic member 2, the probe 6 is inserted into the surface of the metallic member 2 at a right angle, and the bottom surface 5 of the rotor 4 is brought into contact with the surface of the metallic member 2 while pressed against the surface of the metallic member 2. As described above, in this case, friction heat is generated in the metallic member 2 around the rotary tool 3 to form the stirred area 8. Then, the rotary tool 3 is moved linearly along one side of the metallic member 2 (direction shown by the arrow in the figure) while rotated clockwise. In this state, the rotary tool 3 reaches a position close to the other end opposite to the starting point (upper right corner in the figure), and the rotary tool 3 is rotated around while rotated clockwise in a vertical state to the surface of the metallic member 2. The rotary tool 3 which has been rotated around is moved linearly toward one end of the metallic member 2 on the starting point side. In this case, the stirred area 8 formed along the motion track of the rotary tool 3 is partially overlapped with the stirred area 8 formed along the motion track of the rotary tool 3 right before it is rotated around. When coming close to one end on the starting point side, the rotary tool 3 is rotated around likewise and moved linearly in the opposite direction so that the motion track thereof is partially overlapped with the motion track formed right before it is rotated around. Such linear movement and U-rotate are repeated alternately to form the stirred areas 8 on almost all the entire surface of the metallic member 2. When the rotary tool 3 reaches a position close to the last corner (lower left corner in the figure), the rotary tool 3 is removed into the surface of the metallic member 2. Note that, in order to insert the rotary tool 3 into the surface of the metallic member 2, the axis of the probe 6 may be inclined in a direction opposite to the moving direction of the rotary tool 3 at several degrees, and the rotary tool 3 may be moved in this state.

FIG. 4(B) is a sectional view taken along the line C-C′ after the rotary tool 3 is moved to form adjacent motion tracks on almost all the entire surface of the metallic member 2. The stirred areas 8 are formed on almost all the area along the mating plane 7 by the movement of the rotary tool 3, they are partially overlapped with one another to form overlapped portions 8a, and the metallic member 2 and the backing plate 1 are joined together by solid-phase bonding. Dynamic re-crystallization occurs in the stirred areas 8 of the metallic member 2 by stirring by means of the rotary tool 3, and static re-crystallization occurs by residual heat after the rotary tool 3 is moved away. Therefore, the metallic member 2 is modified to become a modified metallic member 9 having a fine crystal structure with a fine crystal grain size. Since the modified metallic member 9 becomes a target material when a film is formed by sputtering, the size and shape of the stirred areas 8 formed in the metallic member 2 can be suitably designed according to the size and shape of a substrate on which the film is to be formed and the like. The modified metallic member 9 may be subjected to surface polishing or mirror finishing when needed.

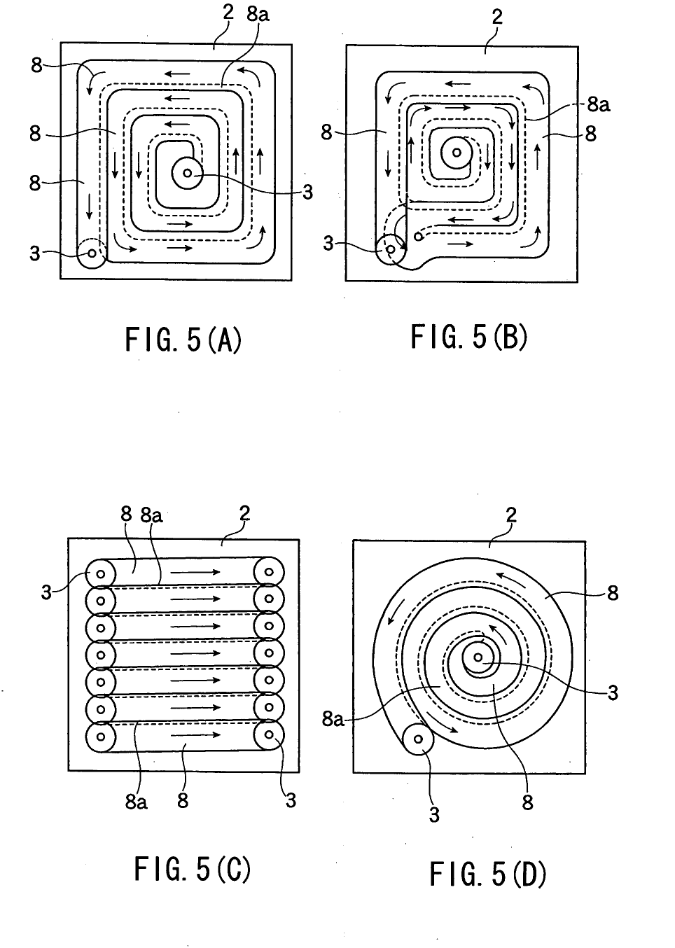

FIGS. 5(A) to 5(D) show the different moving patterns of the rotary tool 3. In FIG. 5(A), the rotary tool 3 is inserted into a position close to the center of the surface of the metallic member 2, and linear movement and L-turn representing a perpendicular turn along each side of the metallic member 2 are repeated alternately from the position serving as a starting point to make the substantially rectangular motion tracks of the rotary tool 3 so as to form the stirred areas 8. The adjacent motion tracks are partially overlapped with each other to form overlapped portions 8a in the stirred areas 8, and the rotary tool 3 is removed at a position close to one corner (lower left corner in the figure) of the metallic member 2.

FIG. 5(B) shows that the rotary tool 3 is inserted into a position close to the center of the surface of the metallic member 2, linear movement and L-turn representing a perpendicular turn along each side of the metallic member 2 are repeated alternately from the position serving as a starting point and U-turn is also made to form the stirred areas 8. The adjacent motion tracks are partially overlapped with each other to form overlapped portions 8a in the stirred areas 8, and the rotary tool 3 is removed at a position close to one corner (lower left corner in the figure) of the metallic member 2.

Further, FIG. 5(C) shows that the rotary tool 3 is inserted into a position close to one corner (upper left corner in the figure) of the metallic member 2 and is moved linearly along one side of the metallic member 2, and when the rotary tool 3 reaches a position close to the other end (upper right corner in the figure) opposite to the starting point, the rotary tool 3 is removed once and then inserted into a position lower than the starting point again and moved linearly likewise so that the motion track of the rotary 3 is partially overlapped with the motion track formed right before. The linear movement and removal and insertion of the rotary tool 3 are repeated, and the adjacent motion tracks are partially overlapped with each other to form stirred areas 8 having an overlapped portion 8a on almost all the entire surface of the metallic member 2.

Still further, FIG. 5(D) shows that the rotary tool 3 is inserted into a position close to one corner (lower left corner in the figure) of the metallic member 2 and is moved spirally toward the center of the metallic member 2 from the position serving as a starting point to form the motion track of the rotary tool 3 which is spiral like a concentric circle so as to form a stirred area 8 having an overlapped portion 8a.

As described above, the backing plate 1 is overlapped with the metallic member 2, the rotary tool 3 is inserted into a position close to the mating plane 7 between the metallic member 2 and the backing plate 1 into the surface of the metallic member 2 to generate friction heat and stir it, and the rotary tool 3 is moved to form adjacent motion tracks in the predetermined planar area of the surface of the metallic member 2 so as to form the stirred areas 8 along the mating plane 7. In this way, the metallic member 2 and the backing plate 1 are joined together by solid-phase bonding, and the metallic member 2 is modified to become a modified metallic member 9. Therefore, a sputtering target X including the modified metallic member 9 as a target material can be obtained. The sputtering target X may be annealed at 150 to 350° C. for 1 to 4 hours when needed or cleaned, and further the peripheral portion of the modified metallic member 9 may be processed and machined to obtain a target material having a predetermined shape.

Since the modified metallic member 9 which is formed of a fine crystal structure having fine crystal grains forms a target material in the sputtering target X obtained as described above, the generation of particles and a splash phenomenon can be prevented even when a film is formed by sputtering. In addition, the modified metallic member 9 has uniform composition and a uniform metal structure due to the elimination of the segregation of a component which may be contained in the metallic member 2, so the obtained film is uniform in composition. Further, because the crystal anisotropy of the metallic member 2 is eliminated and the recrystallized grains of the fine crystal structure have a random direction, a film uniform in thickness can be formed. Since the sputtering target X includes the modified metallic member 9 as a target material, the target material and the backing plate 1 are directly bonded together. Even when the sputtering target X is used in a sputtering apparatus to be heated, there is no possibility that the target material does not come off by distortion. Heat conductivity between the target material and the backing plate 1 is excellent.

[Regeneration of Used Sputtering Target]

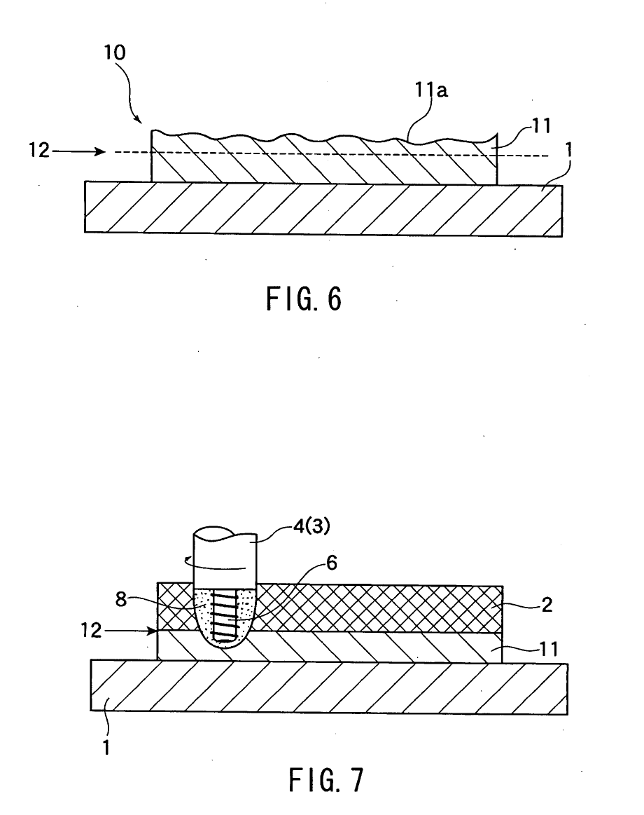

FIG. 6 is an explanatory sectional view of a used sputtering target 10 which has been used in a sputtering apparatus for a predetermined cumulative time to serve out its life. A used target material 11 is bonded to the backing plate 1 in the used sputtering target 10, and the used target material 11 has surface unevenness 11a formed by consumption in places.

The surface of the used target material 11 is cut first by being polished or machined to form a regenerated reference plane 12 at a position devoid of surface unevenness 11a (shown by broken line in the figure). As shown in FIG. 7, a flat plate metallic member 2 is then overlapped on the regenerated reference plane 12 formed on the used target material 11. The metallic member 2 is made of the same material as the used target material 11 and its size and planar shape are the same as those of the used target material 11. Further, the rotary tool 3 is rotated at a rotation speed of 300 to 1,500 rpm, and 1.5 to 15 kN press force is applied to the surface of the metallic member 2 along the axis of the rotary tool 3 to insert the rotary tool 3 into the surface of the metallic member 2 so that the bottom surface 5 of the rotor 4 is buried into the surface of the metallic member 2 by x=0.5 to 1.0 mm. In this case, the distal end of the probe 6 is brought into direct contact with the used target material 11. A portion around the rotary tool 3 of the metallic member 2 into which the rotary tool 3 has been inserted is softened by friction heat and stirred in a solid-phase state to form a stirred area 8 which is a plastic flow area.

The rotary tool 3 is then moved at a traverse speed of 200 to 1,000 mm/min while the state described above is maintained to form adjacent motion tracks in the predetermined planar area of the metallic member 2 so as to form the stirred areas 8 along the regeneration reference plane 12. As a result, the metallic member 2 and the used target material 11 are bonded together and the metallic member 2 is modified to obtain a modified metallic member. The movement pattern and the like of the rotary tool 3 may be the same as those of the manufacture of the sputtering target X which has been described above. This makes it possible to manufacture a new regenerated sputtering target from the used sputtering target 10. As for the obtained regenerated sputtering target, the modified metallic member 9 may be optionally subjected to surface polishing or mirror finishing likewise, or annealed or cleaned. Further, the periphery of the modified metallic member 9 may be machined into a predetermined shape as a target material.

Since the regenerated sputtering target obtained by the regenerating method described above includes the modified metallic member 9 as a target material obtained by modifying the metallic member 2, even when a film is formed by sputtering, the generation of particles and a splash phenomenon can be prevented and a high-quality film which is uniform in composition and thickness can be obtained likewise. The modified metallic member 9 is made of the same material as the used target material 11 in the regenerated sputtering target, so there is little difference in the quality of the target material between before and after regeneration. Therefore, when used for sputtering, the regenerated sputtering target can be used continuously from the target material which is composed of the modified metallic member 9 to the used target material 11. Further, because the target material composed of the modified metallic member 9 and the used target material 11 are directly bonded to each other, distortion does not occur by heat and heat conductivity is excellent.

The present invention will described in more detail with reference to Examples in the following.

### EXAMPLE 1

### Selection of Processing Conditions by Rotary Tool

A rotary tool I and a rotary tool II shown in Table 1 were inserted into the surface of a metal material (thickness of 10 mm, width of 100 mm, length of 300 mm) made of 99.99% aluminum while they were rotated. The rotary tool I and the rotary tool II were moved linearly along the lengthwise direction, and friction stirring was carried out to form stirred areas, which were then evaluated. Note that, when the rotary tool was inserted, 1.8 kN press force and 7 kN press force were applied to the surface of the metallic member for the rotary tool I and the rotary tool II along the axis of the rotary tools, respectively, so the bottom surfaces of the rotors of the rotary tools I and II were buried into the surface of the metallic member by about 0.5 mm. The rotary tools I and II were made of SKD61.

TABLE 1

| | | Diameter D | | |
|---|---|---|---|---|
| | | of bottom | Diameter d | |
| | | surface of | of probe | Length L of |
| | Material | rotor (mm) | (mm) | probe (mm) |
| Rotary tool I | SKD61 | 15 | 6 | 6 |
| Rotary tool II | SKD61 | 30 | 10 | 6 |

Friction stirring was carried out at a rotation speed and a traverse speed shown in Table 2 by using the rotary tools I and II to form stirred areas, and the appearances of the stirred areas which appeared on the surface portion of the metallic member were visually evaluated. Evaluation was conducted based on the four stages. ∘: appearance was satisfactory, Δ: burrs were produced, x: tunnel defect was produced, and xx: rotary tool stopped. The results are shown in Table 2.

TABLE 2

| | | Peripheral Speeds | | | | | | |
|---|---|---|---|---|---|---|---|---|
| | | (mm/min) | | | | | | |
| | | Upper column: speed | | | | | | |
| | | B of bottom surface | | | | | | |
| | | of rotor | | | | | | |
| | Rotation | Lower column: speed | traverse speed A (mm/min) | | | | | |
| | speed | C of probe | 100 | 300 | 500 | 600 | 700 | 900 |
| Rotary | 700 | | x | x | — | x | — | x |
| tool I | | 32970 | 330 | 110 | — | 55 | — | 37 |
| | | 13188 | 132 | 44 | — | 22 | — | 15 |
| | 1000 | | Δ | ∘ | — | ∘ | — | x |
| | | 47100 | 471 | 157 | — | 79 | — | 52 |
| | | 18840 | 188 | 63 | — | 31 | — | 21 |
| | 1400 | | Δ | ∘ | — | ∘ | — | ∘ |
| | | 65940 | 659 | 220 | — | 110 | — | 73 |
| | | 26376 | 264 | 88 | — | 44 | — | 29 |
| Rotary | 400 | | ∘ | ∘ | ∘ | — | xx | — |
| tool II | | 37680 | 377 | 126 | 75 | — | 54 | — |
| | | 15072 | 151 | 50 | 30 | — | 22 | — |
| | 500 | | Δ | ∘ | ∘ | — | x | — |
| | | 47100 | 471 | 157 | 94 | — | 67 | — |
| | | 18840 | 188 | 63 | 38 | — | 27 | — |
| | 600 | | Δ | ∘ | ∘ | — | ∘ | — |
| | | 56520 | 565 | 188 | 113 | — | 81 | — |
| | | 22608 | 226 | 75 | 45 | — | 32 | — |
| | 700 | | Δ | Δ | ∘ | — | ∘ | — |
| | | 65940 | 659 | 220 | 132 | — | 94 | — |
| | | 26376 | 264 | 88 | 53 | — | 38 | — |

<how to look at the table> regarding columns where the rotation speed and the traverse speed cross each other
* The upper column is for the evaluation of the appearance of the stirred area formed by friction stirring.
∘: satisfactory,
Δ: production of burrs,
x: production of defect,
xx: stoppage of rotary tool
(for example, “x“ evaluates a case where the rotary tool I is moved at a traverse speed 100 mm/min at 700 rpm)
* The numerical value in the middle column indicates the ratio (B/A) of the peripheral speed B of the bottom surface of the rotor to the traverse speed A of the rotary tool. (for example, “330” evaluates a case where the rotary tool I is moved at a traverse speed of 100 mm/min at 700 rpm)
* The numerical value in the lower column indicates the ratio (C/A) of the peripheral speed C of the probe to the traverse speed A of the rotary tool. (for example, “132” evaluates a case where the rotary tool I is moved at a traverse speed of 100 mm/min at 700 rpm)

The conditions such as the rotation speed and the traverse speed at which a good stirred area is formed differ according to the rotary tool I and the rotary tool II. However, when the ratio (B/A) of the peripheral speed B of the bottom surface of the rotor to the traverse speed A or the ratio (C/A) of the peripheral speed C of the probe to the traverse speed A is used, the appearance of the stirred area can be evaluated with the same index regardless of the shape of the rotary tool. That is, the inventors of the present invention have found, from the results of the Table 2 and a large number of experiments they had conducted, that when the ratio (B/A) of the peripheral speed B of the bottom surface of the rotor to the traverse speed A was in a range of 70 to 370 or when the ratio (C/A) of the peripheral speed C of the probe to the traverse speed A of the rotary tool was in a range of 30 to 90, stirred areas free from burrs, a tunnel defect, and methoding fluctuations could be formed and a modified metal material obtained by modifying the metallic member could be used as a target material without any problem.

[Confirmation of Modification of Metallic Member]

The crystal grain size in the stirred area of the metallic member obtained when the rotary tool I was rotated at 1,400 rpm was measured. For the measurement, the metallic member was treated by anodic oxidation in an aqueous solution of borofluoric acid and was observed through a polarization microscope to obtain a photomicrograph of the stirred area. The crystal grain size was measured from the obtained photomicrograph by a crosscut method. The results are shown in Table 3.

TABLE 3

| | Traverse speed (mm/min) | | | |
|---|---|---|---|---|
| Rotation speed (rpm) | 100 | 300 | 600 | 900 |
| 1400 | 20 μm | 16 μm | 14 μm | 12 μm |

The results shown above confirm that fine crystal grains having a diameter of 20 μm or less were obtained and that the metallic member was modified.

[Confirmation of the Effect of Annealing]

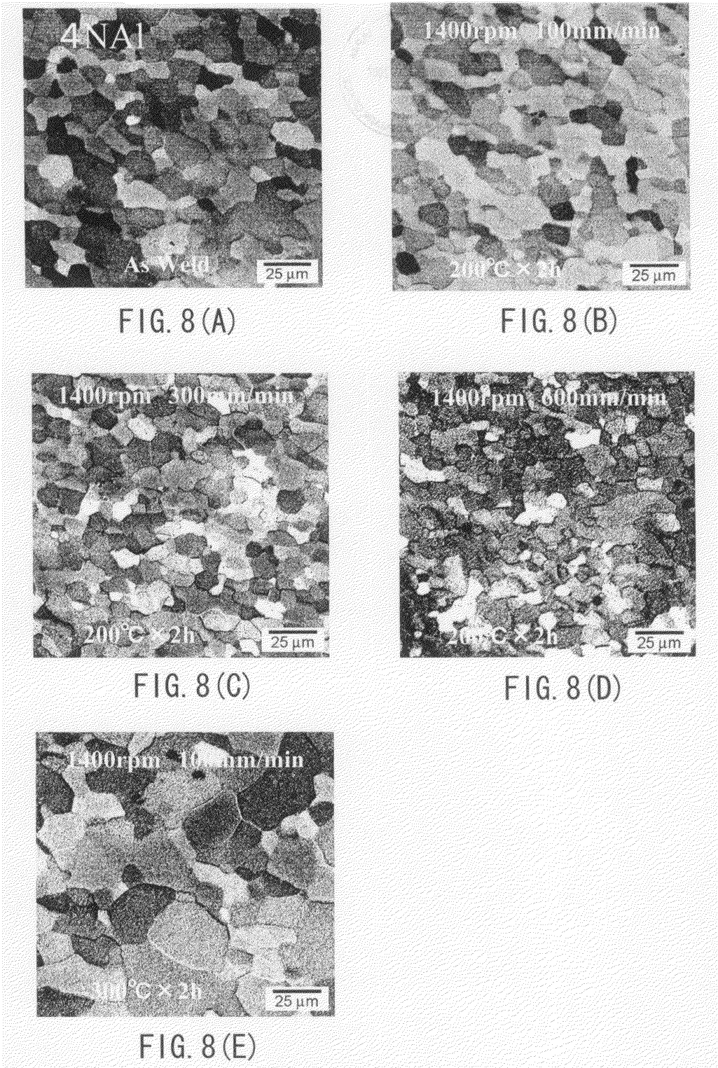

The metallic members whose modification was confirmed were further annealed to check the effect of annealing. The metallic members obtained by changing the traverse speed were annealed in the atmosphere at 200° C. and 300° C. for 2 hours by using a heating furnace. FIGS. 8(A) to 8(E) are polarization photomicrographs of stirred areas after annealing of the metallic members, which were taken in the same manner as in the method of checking the modification of the metallic members. FIG. 8(B) is a photomicrograph of a stirred area formed under such conditions as a rotation speed of 1,400 rpm, a traverse speed of 100 mm/min, an annealing temperature of 200° C., and an annealing time of 2 hours. Similarly, FIG. 8(C) is a photomicrograph of a stirred area formed under such conditions as a rotation speed of 1,400 rpm, a traverse speed of 300 mm/min, an annealing temperature of 200° C., and an annealing time of 2 hours, FIG. 8(D) is a photomicrograph of a stirred area formed under such conditions as a rotation speed of 1,400 rpm, a traverse speed of 600 mm/min, an annealing temperature of 200° C., and an annealing time of 2 hours, and FIG. 8(E) is a photomicrograph of a stirred area formed under such conditions as a rotation speed of 1,400 rpm, a traverse speed of 100 mm/min, an annealing temperature of 300° C., and an annealing time of 2 hours. FIG. 8(A) is a polarization photomicrograph of the stirred area right after friction stirring was carried out at a rotation speed of 1,400 rpm and a traverse speed of 300 mm/min (without annealing). As obvious from FIGS. 8(A) to 8(E), it was confirmed that a finer crystal grain size compared with the crystal grain size right after friction stirring was obtained. In FIG. 8(E), because the annealing temperature was higher than others, it is probable that some recrystallized grains became large in size.

### EXAMPLE 2

An aluminum plate 2 (thickness of 6 mm, length of 500 mm, width of 100 mm) made of 99.99% aluminum was overlapped with a Cu (1020 alloy) backing plate 1 (thickness of 10 mm, length of 500 mm, width of 100 mm) to manufacture a sputtering target X by the method of manufacturing a sputtering target of the present invention. As for a rotary tool 3 in use, the diameter D of the bottom surface 5 of a rotor 4 was 30 mm, the diameter d of a probe 6 was 12 mm, the length L of the probe 6 was 5.5 mm, the rotation speed was 500 rpm, and the traverse speed was 300 m/min.

The rotary tool 3 was placed at a position close to one corner of the surface of the aluminum plate 2 overlapped with the backing plate 1, and 7 kN press force was applied to the surface of the aluminum plate 2 along the axis of the rotary tool 3 to insert the rotary tool 3 into the surface of the aluminum plate 2 while it was rotated (clockwise) so that the bottom surface 5 of the rotor 4 was buried into the surface of the aluminum plate 2 by x=0.5 mm. The rotary tool 3 was moved linearly along one side of the aluminum plate 2 while it was rotated, linear movement and U-rotate were repeated as shown in FIG. 4(A), and friction stirring was carried out to form adjacent motion tracks in a 400 mm×70 mm area of the surface of the aluminum plate 2 so as to form stirred areas 8 along the mating plane 7 between the backing plate 1 and the aluminum plate 2. In this case, the adjacent motion tracks of the bottom surface 5 of the rotor 4 of the rotary tool 3 were overlapped with each other by a width of 20 mm to form overlapped portions 8a of the stirred areas (overlapped portions of the motion tracks at the distal end of the probe 6 were 2 mm). Therefore, the aluminum plate 2 was bonded to the backing plate 1, and a sputtering target X having the modified aluminum plate 9 obtained by modifying the aluminum plate 2 was obtained.

When the crystal structure around the center of the modified aluminum plate 9 obtained as described above was observed through a polarization microscope, it was confirmed that the aluminum plate 2 was modified into a fine crystal structure having a fine crystal grain size of about 10 μm. It was also confirmed that the modified aluminum plate 9 and the backing plate 1 were bonded together firmly along the mating plane 7 and that Cu as the component of the backing plate 1 was rarely contained in the modified aluminum plate 9. When the bonding plane between the modified aluminum plate 9 and the backing plate 1 was observed at a high magnification, an Al—Cu-based intermetallic compound was not confirmed. Therefore, it is probable that even if the Al—Cu-based intermetallic compound was formed, its thickness would be about several μm or less at most.

Consequently, the aluminum plate 2 is thus modified into a modified aluminum plate 9 having a fine crystal grain size. When the modified aluminum plate 9 is used as a target material, it is possible to prevent the generation of particles and a splash phenomenon. The segregation of the component is eliminated in the modified aluminum plate 9, and the modified aluminum plate 9 has uniform composition and a uniform metal structure, so the anisotropy of the aluminum plate 2 is eliminated, and the recrystallized grains of the fine crystal structure have a random direction. As a result, a film uniform in thickness and composition can be obtained.

Since the target material which is the modified aluminum plate 9 and the backing plate 1 are directly bonded together in the sputtering target X, there is no possibility that the target material does not come off due to distortion caused by heating, and further, heat conductivity between the target material and the backing plate 1 is excellent.

### EXAMPLE 3

An aluminum plate 2 made of 99.99% aluminum (thickness of 6 mm, length of 500 mm, width of 100 mm) was overlapped with an A6061 alloy backing plate 1 (thickness of 10 mm, length of 500 mm, width of 100 mm) to manufacture a sputtering target X by the method of manufacturing a sputtering target of the present invention. As for the rotary tool 3 in use, the diameter D of the bottom surface 5 of the rotor 4 was 30 mm, the diameter d of the probe 6 was 12 mm, and the length L of the probe 6 was 6.5 mm. A 1 mm thick distal end portion of the probe 6 was processed in to a hexagonal cylinder-like form having a hexagonal plane with a diagonal line of 10 mm. Since the distal end portion of the probe 6 was made to be like a hexagonal cylinder, the amount of heat generated by rotation could be increased. The diameter (diagonal line width of a hexagonal plane of 10 mm) of the hexagonal cylinder portion at the distal end of the probe 6 was made to be smaller than the diameter of the other portion of the probe 6, so the hoist of the backing plate 1 could be suppressed.

7 kN press force was applied to the surface of the aluminum plate 2 along the axis of the rotary tool 3 while the rotary tool 3 was rotated clockwise at a rotation speed of 500 rpm to insert the rotary tool 3 into the surface of the aluminum plate 2 so that the bottom surface 5 of the rotor 4 was buried into the surface of the aluminum plate 2 by x=0.5 mm. In this case, the distal end of the probe 6 was inserted 1.0 mm into the backing plate 1. The rotary tool 3 was moved in the same manner as in Example 2, and friction stirring was carried out to form adjacent motion tracks in a 400 mm×70 mm area of the surface of the aluminum plate 2 so as to form stirred areas 8 along the mating plane 7 between the backing plate 1 and the aluminum plate 2. Therefore, the aluminum plate 2 was bonded to the backing plate 1, and a sputtering target X having the modified aluminum plate 9 obtained by modifying the aluminum plate 2 was obtained.

When the crystal structure around the center of the modified aluminum plate 9 obtained as described above was observed through a polarization microscope, it was confirmed that the aluminum plate 2 was modified into a fine crystal structure having a fine crystal grain size of about 10 μm. Further, the modified aluminum plate 9 and the backing plate 1 was bonded together by friction-stir welding.

Therefore, when the modified aluminum plate 9 of the sputtering target X obtained in Example 3 is used as a target material like the sputtering target X obtained in Example 2, it is possible to prevent the generation of particles and a splash phenomenon and to obtain a film uniform in thickness and composition.

Since the target material which is the modified aluminum plate 9 and the backing plate 1 are bonded together by friction-stir welding in the sputtering target X, the target material does not come off due to distortion caused by heating and further heat conductivity between the target material and the backing plate 1 is excellent.

### INDUSTRIAL APPLICABILITY

According to the method of manufacturing a metal double-layer structure of the present invention, because the metallic member is modified into a modified metallic member while the metallic member is bonded to a plate material, a sputtering target including the modified metallic member as a target material can be obtained, for example. That is, according to the present invention, a sputtering target which is used for the manufacture of a semiconductor device, magnetic disk, optical disk, liquid crystal or flat panel display typified by plasma displays or the like can be easily manufactured at low cost. In particular, because restrictions on the apparatus and all the problems such as nonuniformity in metal structure that constitute barriers to the increase in size of a sputtering target can be resolved by the manufacturing method, the effect of the present invention is significant in the manufacturing field of liquid crystals and flat panel displays such as plasma panel displays, organic EL, and field emission displays which require the methoding of a glass substrate having an area of more than 1 m².

The metal double-layer structure may also be used as a member for various semiconductor electronic materials including a sputtering target and also as a panel for construction materials external plate for transport machines, highly molded plate material, or the like, a high-quality product can be obtained likewise, and demand for large-sized products can be met. Therefore, the effect of the present invention is significant.

Further, because a used sputtering target which has been regenerated at high cost or scrapped in some cases according to the circumstances can be easily regenerated at low cost by the method of regenerating a sputtering target of the present invention, the regenerating method is advantageous not only in the place where the sputtering target is manufactured or used but also in the field relating to the recycling of the sputtering target.

1. A method of manufacturing a metal double-layer structure by bonding a modified metallic member obtained by modifying a flat plate metallic member to a plate material to join them together, comprising the steps of:
overlapping the plate material with the metallic member;
inserting a rotary tool having a rotor and a probe projecting from a bottom surface of the rotor into a surface of the metallic member while rotated;
bringing a distal end of the probe to a position close to a mating plane between the metallic member and the plate material to generate friction heat and stir the distal end, and moving the rotary tool to form adjacent motion tracks on the surface of the metallic member; and
forming stirred areas along the mating plane to bond the metallic member and the plate material together, and modifying the metallic member into a modified metallic member.

2. A method of manufacturing a metal double-layer structure according to claim 1, wherein the stirred areas are formed only in the metallic member.

3. A method of manufacturing a metal double-layer structure according to claim 1, wherein the adjacent motion tracks of the rotary tool are partially overlapped with each other.

4. A method of manufacturing a metal double-layer structure according to claim 1, wherein the bottom surface of the rotor is in contact with the surface of the metallic member, and there is a predetermined interval between the distal end of the probe and the mating plane.

5. A method of manufacturing a metal double-layer structure according to claim 1, wherein the modified metallic member has a fine crystal structure with a grain diameter of 20 μm or less.

6. A method of manufacturing a metal double-layer structure according to claim 1, wherein the metallic member is made of aluminum, titanium, silver, or alloy thereof, and the plate material is made of copper, aluminum or aluminum alloy.

7. A method of manufacturing a metal double-layer structure according to claim 6, wherein, when the metallic member is made of aluminum or aluminum alloy, the ratio (B/A) of the peripheral speed B of the bottom surface of the rotor with respect to the traverse speed A of the rotary tool is in the range of 70 to 370, and the ratio (C/A) of the peripheral speed C of the probe with respect to the traverse speed A of the rotary tool is in the range of 30 to 90.

8. A method of manufacturing a metal double-layer structure according to claim 1, wherein, after the metallic member is modified to obtain a modified metallic member, annealing is further carried out.

9. A method of manufacturing a sputtering target by using the method of claim 1, wherein the modified metallic member is a target material and the plate material is a backing plate.

10. A metal double-layer structure formed by bonding a modified metallic member obtained by modifying a flat plate metallic member to a plate material to join them together, comprising:
the plate material overlapped with the metallic member;
a rotary tool, having a rotor and a probe projecting from the bottom surface of the rotor, inserted into the surface of the metallic member while rotated;
a distal end of the probe brought to a position close to a mating plane between the metallic member and the plate material to generate friction heat and stir the distal end, the rotary tool which is moved to form adjacent motion tracks on the surface of the metallic member; and
stirred areas formed along the mating plane to bond the metallic member and the plate material together, and the metallic member which is modified into a modified metallic member.

11. A metal double-layer structure according to claim 10, wherein the modified metallic member has a fine crystal structure with a grain diameter of 20 μm or less.

12. A sputtering target which is the metal double-layer structure according to claim 10 or 11, wherein the modified metallic member serves as a target material.

13. A method of regenerating a sputtering target by bonding a target material which is a modified metallic member obtained by modifying a flat plate metallic member to a used sputtering target to joint them together, comprising the steps of:
grinding or polishing the surface of the used sputtering target to form a regenerated reference plane;
overlapping a metallic member with the regenerated reference plane;
inserting a rotary tool having a rotor and a probe projecting from a bottom surface of the rotor into a surface of the metallic member while rotated;
bringing a distal end of the probe to a position close to the regenerated reference plane to generate friction heat and stir the distal end; and
moving the rotary tool to form adjacent motion tracks on the surface of the metallic member to form stirred areas along the regenerated reference plane so as to bond the metallic member to the regenerated reference plane and modifying the metallic member into a modified metallic member.

14. A method of regenerating a sputtering target according to claim 13, wherein, when the regenerated reference plane is formed with part of the used target material of the used sputtering target, the stirred areas are formed in both the metallic member and the target material of the used sputtering target with the regenerated reference plane therebetween.

15. A method of regenerating a sputtering target according to claim 14, wherein the bottom surface of the rotor is in contact with the surface of the metallic member, and the distal end of the probe is in direct contact with the used target material.
